(19) United States
(12) Patent Application Publication
(10) Pub. No.: US 2016/0308072 A1
(43) Pub. Date: Oct. 20, 2016

(54) SEMICONDUCTOR DEVICE HAVING EDGE TERMINATION STRUCTURE INCLUDING HIGH-CONCENTRATION REGION AND LOW-CONCENTRATION REGION

(71) Applicant: Panasonic Intellectual Property Management Co., Ltd., Osaka (JP)

(72) Inventors: MASAO UCHIDA, Osaka (JP); KOUICHI SAITOU, Toyama (JP); TAKAYUKI WAKAYAMA, Toyama (JP); MASASHI HAYASHI, Osaka (JP); TATSUYA KUNISATO, Osaka (JP)

(21) Appl. No.: 15/089,383

(22) Filed: Apr. 1, 2016

(30) Foreign Application Priority Data
Apr. 15, 2015 (JP) 2015-083369

(51) Int. Cl. H01L 29/872; H01L 29/06; H01L 29/16

(52) U.S. Cl. CPC H01L 29/872; H01L 29/1608; H01L 29/0623; H01L 29/063

(57) ABSTRACT

A semiconductor device according to an aspect of the present disclosure includes a semiconductor substrate having a first conductivity type and having a principal surface and a back surface, a silicon carbide semiconductor layer having the first conductivity type and disposed on the principal surface of the semiconductor substrate, a guard ring region having a second conductivity type and disposed within the silicon carbide semiconductor layer, a floating region having the second conductivity type and disposed within the silicon carbide semiconductor layer, a first electrode disposed on the silicon carbide semiconductor layer, and a second electrode disposed on the back surface of the semiconductor substrate, wherein the guard ring region and the floating region each include a pair of a high-concentration region having the second conductivity type and a low-concentration region having the second conductivity type.

### BACKGROUND

1. Technical Field

The present disclosure relates to semiconductor devices and methods for manufacturing the same. In particular, the present disclosure relates to semiconductor devices including silicon carbide, and to methods for manufacturing the same.

2. Description of the Related Art

Silicon carbide (SiC) is a semiconductor material having a larger bandgap and a higher hardness than silicon (Si). For example, SiC is used in power devices such as switching devices and rectifying devices. SiC power devices have advantages over Si power devices such as low power loss.

Some typical semiconductor devices using SiC are metal-insulator-semiconductor field-effect transistors (MISFETs) and Schottky-barrier diodes (SBDs). Metal-oxide-semiconductor field-effect transistors (MOSFETs) are a type of MISFETs, and junction-barrier Schottky diodes (JBSs) are a type of SBDs.

A JBS includes a first conductivity type semiconductor layer, a plurality of second conductivity type regions disposed in contact with the first conductivity type semiconductor layer, and a Schottky electrode forming a Schottky junction with the first conductivity type semiconductor layer. Because of having a plurality of second conductivity type regions, the JBS achieves a reduction in leakage current when reverse-biased as compared to an SBD (see, for example, Japanese Unexamined Patent Application Publication No. 2014-60276).

### SUMMARY

In one general aspect, the techniques disclosed here feature a semiconductor device including a semiconductor substrate having a first conductivity type and having a principal surface and a back surface, a silicon carbide semiconductor layer having the first conductivity type and disposed on the principal surface of the semiconductor substrate, a guard ring region having a second conductivity type and disposed within the silicon carbide semiconductor layer, a floating region having the second conductivity type and disposed within the silicon carbide semiconductor layer, a first electrode disposed on the silicon carbide semiconductor layer and forming a Schottky junction with the silicon carbide semiconductor layer, and a second electrode disposed on the back surface of the semiconductor substrate and forming an ohmic junction with the semiconductor substrate, wherein the guard ring region encloses a portion of a surface of the silicon carbide semiconductor layer as viewed in a direction normal to the principal surface, the first electrode has a surface in contact with the silicon carbide semiconductor layer, the first electrode is in contact with the guard ring region along an edge portion of the surface of the first electrode in contact with the silicon carbide semiconductor layer, the floating region is disposed out of contact with the guard ring region, the floating region enclosing the guard ring region as viewed in the direction normal to the principal surface, the guard ring region and the floating region each include a pair of a high-concentration region having the second conductivity type and a low-concentration region having the second conductivity type, the high-concentration regions are disposed in contact with the surface of the silicon carbide semiconductor layer, the low-concentration regions are disposed between the semiconductor substrate and the high-concentration regions, and the high-concentration regions have an impurity concentration higher than the impurity concentration in the low-concentration regions.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a sectional view schematically illustrating a semiconductor device according to a first embodiment;

FIG. 2 is a plan view schematically illustrating a silicon carbide semiconductor layer in the semiconductor device;

FIG. 3 is an exemplary diagram illustrating implantation profiles of the impurity concentration in edge termination regions, in the direction of thickness of p-type implanted regions;

FIG. 4 is a cumulative frequency distribution illustrating relationships between the profile of the impurity concentration in the p-type implanted regions, and the breakdown voltage;

FIG. 5 is a sectional view schematically illustrating a step in the manufacturing of the semiconductor device according to the first embodiment;

FIG. 6 is a sectional view schematically illustrating a step in the manufacturing of the semiconductor device according to the first embodiment;

FIG. 7 is a sectional view schematically illustrating a step in the manufacturing of the semiconductor device according to the first embodiment;

FIG. 8 is a sectional view schematically illustrating a step in the manufacturing of the semiconductor device according to the first embodiment;

FIG. 9 is a sectional view schematically illustrating a step in the manufacturing of the semiconductor device according to the first embodiment;

FIG. 10 is a sectional view schematically illustrating a step in the manufacturing of the semiconductor device according to the first embodiment;

FIG. 11 is a sectional view schematically illustrating a step in the manufacturing of the semiconductor device according to the first embodiment;

FIG. 12 is a sectional view schematically illustrating a step in the manufacturing of the semiconductor device according to the first embodiment;

FIG. 13 is a sectional view schematically illustrating a step in the manufacturing of the semiconductor device according to the first embodiment;

FIG. 14 is a sectional view schematically illustrating a semiconductor device according to Modified Example 1;

FIG. 15 is a plan view schematically illustrating a silicon carbide semiconductor layer in the semiconductor device;

FIG. 16 is a sectional view schematically illustrating a semiconductor device according to Modified Example 2; and

FIG. 17 is a plan view schematically illustrating a silicon carbide semiconductor layer in the semiconductor device.

### DETAILED DESCRIPTION

A summary of the present disclosure is described below.

An aspect of the present disclosure resides in a semiconductor device including a semiconductor substrate having a first conductivity type and having a principal surface and a back surface, a silicon carbide semiconductor layer having the first conductivity type and disposed on the principal surface of the semiconductor substrate, a guard ring region having a second conductivity type and disposed within the silicon carbide semiconductor layer, a floating region having the second conductivity type and disposed within the silicon carbide semiconductor layer, a first electrode disposed on the silicon carbide semiconductor layer and forming a Schottky junction with the silicon carbide semiconductor layer, and a second electrode disposed on the back surface of the semiconductor substrate and forming an ohmic junction with the semiconductor substrate, wherein the guard ring region encloses a portion of a surface of the silicon carbide semiconductor layer as viewed in a direction normal to the principal surface, the first electrode has a surface in contact with the silicon carbide semiconductor layer, the first electrode is in contact with the guard ring region along an edge portion of the surface of the first electrode in contact with the silicon carbide semiconductor layer, the floating region is disposed out of contact with the guard ring region, the floating region enclosing the guard ring region as viewed in the direction normal to the principal surface, the guard ring region and the floating region each include a pair of a high-concentration region having the second conductivity type and a low-concentration region having the second conductivity type, the high-concentration regions are disposed in contact with the surface of the silicon carbide semiconductor layer, the low-concentration regions are disposed between the semiconductor substrate and the high-concentration regions, and the high-concentration regions have an impurity concentration higher than the impurity concentration in the low-concentration regions. With this configuration, the electric field concentration in the edge termination regions is reduced, and the semiconductor device achieves a higher breakdown voltage.

In the semiconductor device according to one aspect of the present disclosure, each pair of the high-concentration region and the low-concentration region may have an identical outline as viewed in the direction normal to the principal surface.

In the semiconductor device according to one aspect of the present disclosure, the impurity concentration in a direction of depth of the low-concentration regions may have a profile including, for example, an upward curve. With this configuration, crystal defects occurring in the pn junctions between the first conductivity type silicon carbide semiconductor layer and the second conductivity type low-concentration regions have a relatively small size, and the leakage current from the pn junctions can be reduced.

In the semiconductor device according to one aspect of the present disclosure, the impurity concentration in the high-concentration regions may be not less than 1×10¹⁹ cm⁻³ and the impurity concentration in the low-concentration regions may be less than 1×10¹⁹ cm⁻³. In an embodiment, the impurity concentration in the high-concentration regions may be not less than 1×10²⁰ cm⁻³ and the impurity concentration in the low-concentration regions may be less than 1×10²⁰ cm⁻³. With this configuration, the electric field concentration in the edge termination regions is further reduced, and the semiconductor device achieves a still higher breakdown voltage.

In the semiconductor device according to one aspect of the present disclosure, the first electrode may be an only metal material that is in contact with the guard ring region. This configuration eliminates the need of providing metal materials other than the first electrode, resulting in the simplification of the process.

In the semiconductor device according to one aspect of the present disclosure, the guard ring region may not form an ohmic junction with the first electrode. With this configuration, the contact resistance between the first electrode and the edge termination region (the guard ring region) can be increased, and the leakage current from the pn junction formed between the edge termination region and the first conductivity type silicon carbide semiconductor layer can be reduced.

In the semiconductor device according to one aspect of the present disclosure, the first electrode may include a metal selected from the group consisting of, for example, Ti, Ni and Mo. With this configuration, the first electrode can easily form a Schottky junction with the first conductivity type silicon carbide semiconductor layer.

The semiconductor device according to one aspect of the present disclosure may further include barrier regions having the second conductivity type and disposed within a portion of the silicon carbide semiconductor layer, the portion enclosed by the guard ring region as viewed in the direction normal to the principal surface. The impurity concentration in the barrier regions may have the same profile in the direction of depth from the surface of the silicon carbide semiconductor layer as the impurity concentration in the guard ring region. With this configuration, a JBS structure can be formed while maintaining the breakdown voltage, and the leakage current in the semiconductor device can be reduced. By configuring the second conductivity type barrier regions and the edge termination regions to have substantially the same profile of the second conductivity type impurity concentration, the simultaneous formation of the barrier regions and the edge termination regions becomes possible, resulting in the simplification of the process.

In the semiconductor device according to one aspect of the present disclosure, each of the barrier regions may have a shape extending in a first direction as viewed in the direction normal to the principal surface. The barrier regions may be arranged with a first spacing S1 in a second direction perpendicular to the first direction. Both ends in the first direction of each of the barrier regions may be connected to the guard ring region. With this configuration, the leakage current in the JBS structure can be further reduced.

In the semiconductor device according to one aspect of the present disclosure, of the barrier regions, the barrier region nearest to the guard ring region as viewed in the direction normal to the principal surface may be adjacent to the guard ring region with a second spacing having a maximum width S2 in the second direction that is equal to or less than the first spacing S1. The satisfaction of S1≧S2 makes it possible to reduce the leakage current from the edge termination region in which electric fields tend to be concentrated.

In the semiconductor device according to one aspect of the present disclosure, the guard ring region as viewed in the direction normal to the principal surface may be adjacent to the floating region with a third spacing S3 in the second direction, the third spacing being equal to or less than the maximum width S2. When S2≧S3 is satisfied, any defects occurring during the formation of the edge termination regions and the barrier regions will occur in the edge termination regions that are arranged with a finer spacing. Thus, a device having such defects can be easily classified as defective by generating a breakdown voltage failure in the initial evaluation of electric characteristics after the fabrication of the semiconductor device. The “defects occurring in the edge termination regions” means defects occurring in the guard ring region or in the field limiting ring (FLR) region that is the floating region.

Any defects present in the edge termination regions can be easily detected by initial evaluation for the reason described below. In general, a semiconductor device is subjected to the initial evaluation of electric characteristics after its fabrication. In the initial evaluation, the presence or absence of breakdown voltage failure is determined by, for example, applying a reverse voltage to the device. As an example, assume that a semiconductor device is designed with twenty FLR regions so that a breakdown voltage of 1700 V may be obtained. If any of the FLR regions is not formed as designed, for example, is discontinued, electric fields are concentrated in that defective area and consequently the device fails to exhibit the designed breakdown voltage when reverse-biased. In this manner, the presence of initial defects can be easily found in the initial evaluation.

The semiconductor device according to one aspect of the present disclosure may further include an insulating film covering at least a portion of the guard ring region, and an upper electrode disposed on an upper surface of the first electrode, the upper electrode covering the upper surface and a side surface of the first electrode, wherein the side surface of the upper electrode may be disposed on the insulating film. With this configuration, the upper electrode can be processed into a desired shape without the process, in particular, the etching process being affected by the presence of the first electrode.

Another aspect of the present disclosure resides in a semiconductor device manufacturing method including providing a first conductivity type semiconductor substrate having a principal surface; forming a first conductivity type silicon carbide semiconductor layer onto the principal surface of the semiconductor substrate: forming a second conductivity type guard ring region and a second conductivity type floating region within the silicon carbide semiconductor layer; forming a plurality of second conductivity type barrier regions within the silicon carbide semiconductor layer; forming a second electrode in ohmic contact with the semiconductor substrate; and forming a first electrode onto the silicon carbide semiconductor layer in Schottky contact with the silicon carbide semiconductor layer; the guard ring region being formed so as to enclose a portion of the surface of the silicon carbide semiconductor layer as viewed in a direction normal to the principal surface; the floating region being formed so as to enclose the guard ring region as viewed in the direction normal to the principal surface; the plurality of second conductivity type barrier regions being formed under the surface of the silicon carbide semiconductor layer enclosed by the guard ring region; the first electrode being in contact with the guard ring region along an edge portion of the surface of the first electrode in contact with the silicon carbide semiconductor layer; the guard ring region, the floating region and the plurality of second conductivity type barrier regions each including a second conductivity type high-concentration region disposed in contact with the surface of the silicon carbide semiconductor layer and a second conductivity type low-concentration region disposed under the high-concentration region and containing a second conductivity type impurity in an impurity concentration lower than the impurity concentration in the high-concentration region. With this configuration, the high-concentration regions and the low-concentration regions can be formed by the same process, and the manufacturing process can be simplified.

The guard ring region, the floating region and the plurality of second conductivity type barrier regions may be formed at the same time. With this configuration, a semiconductor device having a JBS structure may be manufactured without involving additional production processes.

The guard ring region and the floating region may be formed by, for example, implanting impurity ions using at least first acceleration energy and second acceleration energy, the first acceleration energy being larger than the second acceleration energy, and the low-concentration regions may be disposed over a range of depths including a depth at which the concentration of the impurity implanted with the first acceleration energy shows an upward curve in an impurity concentration profile in the direction of depth. With this configuration, the high-concentration regions and the low-concentration regions can be easily formed by controlling the magnitudes of acceleration energy and the implantation doses in the impurity implantation process.

### First Embodiment

Hereinbelow, the first embodiment of the present disclosure will be described with reference to the drawings. While the first embodiment illustrates the first conductivity type as being n-type and the second conductivity type as p-type, the conductivity types in the first embodiment are not limited thereto and the first conductivity type may be p-type and the second conductivity type may be n-type.

### (Structure of Semiconductor Devices)

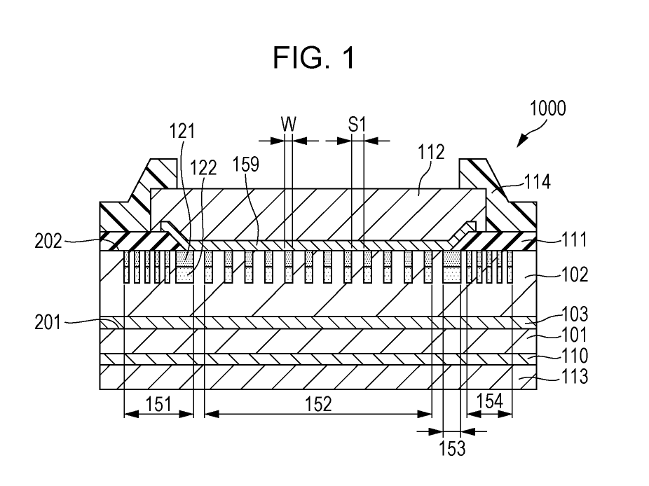

A semiconductor device 1000 according to the first embodiment will be described with reference to FIGS. 1 to 13.

FIG. 1 is a sectional view schematically illustrating the semiconductor device 1000 according to the present embodiment.

The semiconductor device 1000 includes a first conductivity type semiconductor substrate 101, and a drift layer 102 that is a first conductivity type silicon carbide semiconductor layer disposed on a principal surface 201 of the semiconductor substrate 101. While FIG. 1 illustrates a buffer layer 103 between the drift layer 102 and the semiconductor substrate 101, the buffer layer 103 may be omitted. Second conductivity type edge termination regions 151 are disposed within the drift layer 102.

A first electrode 159 is disposed on the drift layer 102. The first electrode 159 forms a Schottky junction with the drift layer 102. The first electrode 159 is in contact with the edge termination region 151 along an edge portion of the electrode surface in contact with the drift layer 102 (the silicon carbide semiconductor layer). The first electrode 159 may be the only metal material that is in contact with the edge termination region 151. The edge termination region 151 may have a non-ohmic junction with the first electrode 159.

A second electrode 110 is disposed on the back surface of the semiconductor substrate 101 opposite to the principal surface 201. The second electrode 110 forms an ohmic junction with the semiconductor substrate 101. A backside electrode 113 is disposed on the lower surface of the second electrode 110, namely, the surface opposite to the semiconductor substrate 101.

As illustrated in FIG. 1, the edge termination regions 151 may include a second conductivity type guard ring region 153 that is in contact with a portion of the first electrode 159, and a plurality of FLR regions 154 that are second conductivity type floating regions disposed so as to enclose the guard ring region 153. The FLR regions 154 are disposed out of contact with the guard ring region 153. The configuration of the edge termination regions 151 is not limited to the one illustrated in the drawings as long as the edge termination regions 151 include at least one guard ring region 153 and at least one FLR region 154 which are disposed to enclose a portion of the surface of the drift layer 102.

A plurality of second conductivity type barrier regions 152 may be disposed within the drift layer 102 so as to be enclosed by the edge termination regions 151 as viewed in the direction normal to the principal surface 201 of the semiconductor substrate 101. The presence of the barrier regions 152 makes it possible to reduce the Schottky leakage current when the Schottky junction formed between the first electrode 159 and the drift layer 102 is reverse-biased.

The edge termination regions 151, which include the guard ring region 153 and the FLR regions 154 in the illustrated example, have second conductivity type high-concentration regions 121 and second conductivity type low-concentration regions 122. Similarly to the edge termination regions 151, the barrier regions 152 may have second conductivity type high-concentration regions 121 and second conductivity type low-concentration regions 122. The high-concentration regions 121 are disposed in contact with a surface 202 of the silicon carbide semiconductor layer (the drift layer 102). The low-concentration regions 122 are disposed under the high-concentration regions 121 and contain a second conductivity type impurity in an impurity concentration lower than the impurity concentration in the high-concentration regions 121. Each pair of the high-concentration region 121 and the low-concentration region 122 may have an identical outline as viewed in the direction normal to the principal surface 201 of the semiconductor substrate 101.

In the illustrated example, an insulating film 111 is disposed on the drift layer 102. The insulating film 111 covers the FLR regions 154 and may cover a portion of the guard ring region 153. Further, an upper electrode 112 may be disposed on the first electrode 159 so as to cover the upper surface and the side surface of the first electrode 159. The side surface of the upper electrode 112 may be disposed on the insulating film 111. A passivation film 114 is disposed on a portion of the insulating film 111 and a portion of the upper electrode 112. The passivation film 114 may cover the side surface and a portion of the upper surface of the upper electrode 112.

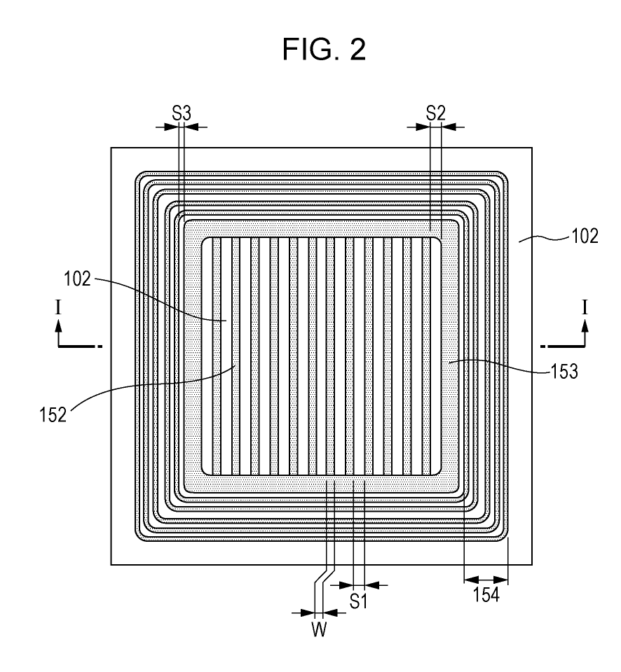

FIG. 2 is an exemplary view illustrating the upper surface of the drift layer 102 in the semiconductor device 1000. Specifically, FIG. 2 is a plan view of the drift layer 102 as viewed in the direction normal to the principal surface 201 of the semiconductor substrate 101. In FIG. 2, the components such as electrodes disposed on the surface 202 of the drift layer 102 are omitted for ease of explanation. FIG. 1 corresponds to a cross section taken along line I-I in FIG. 2.

In the example illustrated in FIG. 2, each of the barrier regions 152 has a stripe shape having a width W and extending in a direction (hereinafter, “first direction”). The barrier regions 152 are arranged parallel to one another with spacings S1 in a second direction perpendicular to the first direction. With this configuration, a depletion layer that extends from an interface between one of the barrier regions 152 and the drift layer 102 is uniformly connected to a depletion layer that extends from an interface between an adjacent barrier region 152 and the drift layer 102, and consequently the leakage current can be further reduced.

Of the plurality of barrier regions 152, the barrier region 152 that is nearest to the edge termination region 151 as viewed in the direction normal to the principal surface 201 of the semiconductor substrate 101 is adjacent to the edge termination region 151 with a spacing having a maximum width S2. In the illustrated example, the maximum width S2 is of the spacing between the guard ring region 153 and the barrier region 152 nearest to the guard ring region 153. The “maximum width” is the maximum distance of the spacing in the second direction. The guard ring region 153 is adjacent to the innermost FLR region 154 with a spacing S3. In the present embodiment, the spacing S1 between the adjacent barrier regions 152 may be equal to or greater than the maximum width S2. Alternatively, the spacing S1 may be greater than the maximum width S2. Further, the maximum width S2 may be equal to or greater than the spacing S3 between the guard ring region 153 and the FLR region 154. Alternatively, the maximum width S2 may be greater than the spacing S3.

An end of each of the barrier regions 152 in the first direction may be connected to the edge termination region 151. In the illustrated example, both ends of each of the barrier regions 152 are connected to the guard ring region 153.

### (Operations of Semiconductor Device 1000)

When a metal-semiconductor Schottky junction or a semiconductor pn junction is reverse-biased, a depletion layer extends at the junction interface. When the field intensity at the junction interface reaches a threshold, an avalanche current flows in the depletion layer and it becomes impossible to further increase the reverse bias. In the present disclosure, the voltage which causes the avalanche current to flow is simply referred to as the “breakdown voltage”.

Hereinbelow, the operations of the semiconductor device 1000 will be described taking the first conductivity type as n-type and the second conductivity type as p-type. The semiconductor device 1000 has a JBS structure. In the semiconductor device 1000, a negative voltage is applied to the first electrode 159 relative to the second electrode 110. As a result, a depletion layer formed between the first electrode 159 and the n-type drift layer 102 extends toward the n-type semiconductor substrate 101. Further, a pn junction is formed between the p-type barrier region 152 and the n-type drift layer 102, and the reverse-biasing causes the depletion layer at the pn junction to extend mainly toward the drift layer 102. The depletion layers extending from the pn junctions of the adjacent barrier regions 152 interrupt the leakage current from the Schottky junctions present between the adjacent barrier regions 152, and consequently the leakage current in the semiconductor device 1000 is reduced. The breakdown voltage is exceeded when the field intensity at a junction interface of a Schottky junction or a pn junction reaches a threshold. The edge termination regions 151 are provided in order to reduce the field intensity on the surface of the drift layer 102.

### (Profiles of Impurity Concentration in Edge Termination Regions 151)

The edge termination regions 151 and the barrier regions 152 in the semiconductor device 1000 may be formed at the same time by, for example, ion implantation. Such simultaneous ion implantation simplifies the process and saves the production costs. For example, the edge termination regions 151 and the barrier regions 152 are formed by implanting Al ions into the drift layer 102. In this process, the edge termination regions 151 and the barrier regions 152 can be formed at the same time so as to include high-concentration regions 121 and low-concentration regions 122 by implanting Al ions a plurality of times while changing the magnitude of energy. In the description hereinbelow, the edge termination regions 151 including the guard ring region 153 and the FLR regions 154, and the barrier regions 152 are collectively written as the “p-type implanted regions”.

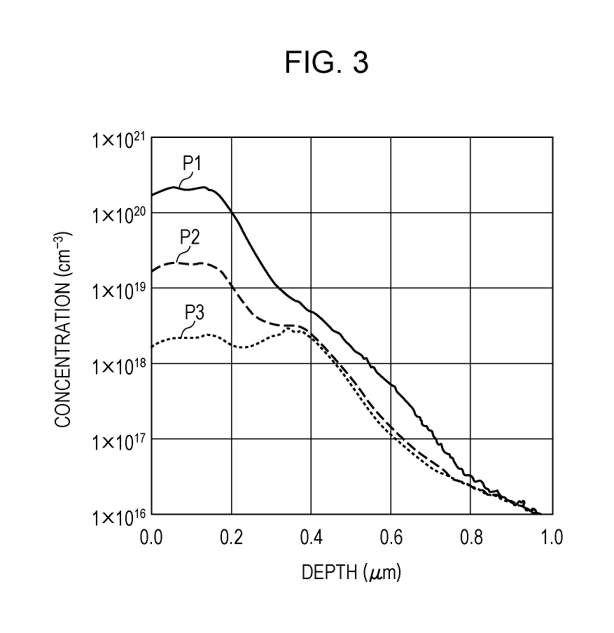

FIG. 3 is an exemplary diagram illustrating profiles, in the direction of depth, of the concentration of p-type impurity ions (here, Al ions) implanted in the p-type implanted regions. The “direction of depth” indicates the direction normal to the principal surface 201 of the semiconductor substrate 101.

The profiles P1 and P2 each show the presence of high-concentration regions near the surface of the drift layer, and the presence of low-concentration regions at greater depths than the high-concentration regions. The profile P3 represents a comparative example in which the implanted regions do not have any high-concentration regions near the surface of the drift layer.

In the example illustrated in FIG. 3, the p-type implanted regions are formed by performing the ion implantation step four times with different magnitudes of implantation energy. For example, the ion implantation profiles shown in FIG. 3 are the sums of profiles obtained by performing the ion implantation step four times. The three types of implantation profiles P1 to P3 are created by changing the implantation dose in the three ion implantation steps except the dose in the ion implantation step carried out with the highest energy.

For example, the magnitudes of implantation energy and the doses in the ion implantation steps are as described below.

TABLE

| | P1 | P2 | P3 |
|---|---|---|---|
| Implantation | 30 keV: 5 × 10¹⁴ cm⁻² | 30 keV: 5 × 10¹³ cm⁻² | 30 keV: 5 × 10¹² cm⁻² |
| conditions | 70 keV: 1.2 × 10¹⁵ cm⁻² | 70 keV: 1.2 × 10¹⁴ cm⁻² | 70 keV: 1.2 × 10¹³ cm⁻² |
| | 150 keV: 2.8 × 10¹⁵ cm⁻² | 150 keV: 2.8 × 10¹⁴ cm⁻² | 150 keV: 2.8 × 10¹³ cm⁻² |
| | 350 keV: 6 × 10¹³ cm⁻² | 350 keV: 6 × 10¹³ cm⁻² | 350 keV: 6 × 10¹³ cm⁻² |

The following description assumes that the impurity ions implanted are 100% activated, and that the implantation profiles shown in FIG. 3 indicate the impurity concentrations in the direction of depth in the p-type implanted regions.

When the p-type implanted regions including the high-concentration regions 121 and the low-concentration regions 122 are formed by implanting ions a plurality of times using different magnitudes of implantation energy, the concentration profile will have an upwardly curved shape (hereinafter, “upward curve”) in each of the high-concentration regions 121 and the low-concentration regions 122 as is the case in the profile P1 or P2 illustrated in FIG. 3, in which the concentration is indicated on the ordinate on the log scale. The upward curve in the concentration profile includes not only a peak and a sub peak, but also a shoulder. The shoulder is a segment in which the slope of the profile, specifically, the rate of the decrease in concentration becomes slow as the depth is increased.

For example, the profile P1 has a peak in the high-concentration regions 121 and a shoulder in the low-concentration regions 122. The edge termination regions 151 may have a concentration of 1×10¹⁸ cm⁻³ or above. The concentrations in the above peak and shoulder may be 1×10¹⁸ cm⁻³ or above. With this configuration, the breakdown voltage can be increased as compared to conventional p-type implanted regions having only one of high-concentration regions and low-concentration regions. Specifically, disposing the low-concentration regions 122 at the bottoms of the p-type implanted regions can reduce the intensity of electric fields at corners of the bottoms of the p-type implanted regions. Further, the high-concentration regions 121 disposed at upper portions of the p-type implanted regions provide a higher impurity concentration at the upper portions of the p-type implanted regions than at the corners of the bottoms of the p-type implanted regions. Consequently, the intensity of electric fields at the corners of the bottoms of the p-type implanted regions is reduced in the direction parallel to the plane of the substrate. As a result, the concentration of electric fields at the corners of the bottoms of the p-type implanted regions is reduced, and the decrease in breakdown voltage associated with the pn junctions between the p-type implanted regions and the drift layer can be suppressed. Further, because the side surfaces of the high-concentration regions 121 are in direct contact with the drift layer 102, the pn junction interfaces formed between the high-concentration regions 121 and the drift layer 102 in the edge termination regions 151 shift toward the drift layer 102. Thus, the effective spacings between the adjacent p-type implanted regions can be reduced. This results in an enhancement in breakdown voltage determined by the edge termination regions 151. When the edge termination regions 151 are the dominant factor that determines the breakdown voltage of the semiconductor device 1000, the breakdown voltage of the device can be further enhanced.

If, in contrast, p-type implanted regions are formed by other than a plurality of ion implantation operations, the implantation profile will have a peak upwardly curved only at a certain depth and will not have an upward curve such as a shoulder in the range of concentrations of 1×10¹⁸ cm⁻³ and above at a greater depth (in a tail). In this case, the advantageous effects described above cannot be obtained and the breakdown voltage may be lowered even when the impurity concentration in the p-type implanted regions is reduced to a level similar to that in the low-concentration regions in the present embodiment or is increased to a level similar to that in the high-concentration regions in the present embodiment.

The low-concentration regions 122 may be formed by implanting ions with a magnitude of energy higher than the impurity implantation energy used for the formation of the high-concentration regions 121. In such a manner, as is the case in the profile P2 or P3 illustrated in FIG. 3, the profile will have a peak or a sub peak at a depth of, for example, 0.3 to 0.4 μm that is distinguished from the peak near the surface of the drift layer 102, namely, near a depth of 0 μm. While the profile P1 does not have such a peak or a sub peak at the corresponding depth, a shoulder that is a gentle upward curve is observed. The method for implanting ions to form the low-concentration regions 122 is not limited to the one described above. The low-concentration regions 122 which show a profile having a shoulder at a prescribed depth can be formed also by performing ion implantation a plurality of times using a relatively low magnitude of energy.

The concentration profile of the p-type implanted regions in the present embodiment is not limited to those illustrated in the drawing. The shape of the concentration profile is variable depending on the ion implantation conditions and the number of the implantation steps adopted in the formation of the p-type implanted regions. Even when the ion implantation conditions and other conditions such as the shape of the concentration profile are different from those described above, advantageous effects similar to those described above can be obtained as long as the p-type implanted regions include the high-concentration regions 121 and the low-concentration regions 122.

The low-concentration regions 122 may be defined as regions in which the concentration does not exceed a prescribed concentration, and the high-concentration regions 121 as regions in which the concentration is equal to or higher than the prescribed concentration. For example, the prescribed concentration may be 1×10¹⁹ cm⁻³. According to this definition, the high-concentration regions 121 in the profile P1 are regions extending to a depth of about 0.3 μm from the surface, and the high-concentration regions 121 in the profile P2 are regions extending to a depth of about 0.2 μm from the surface. Because the profile P3 lies below an impurity concentration of 1×10¹⁹ cm⁻³, the p-type implanted regions do not include any high-concentration regions 121 and are entirely composed of low-concentration regions 122. The prescribed concentration may be 1×10²⁰ cm⁻³.

Next, relationships studied between the profile of the concentration in edge termination regions and the breakdown voltage with respect to devices having a JBS structure will be discussed.

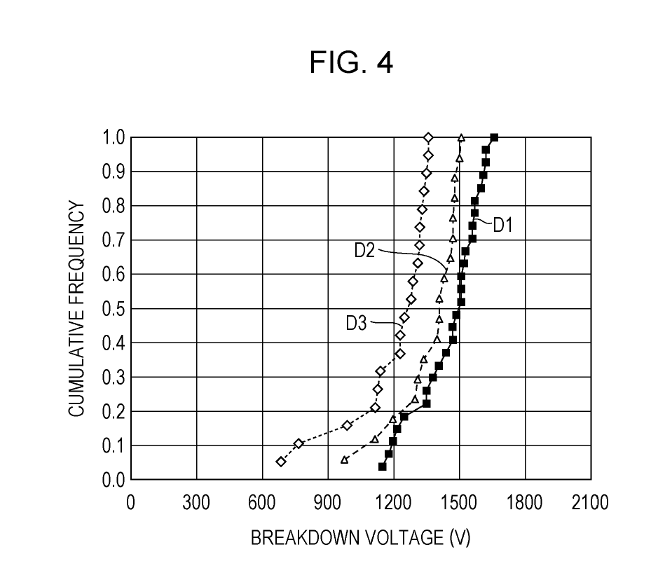

Devices D1, D2 and D3 having different profiles of the concentration in edge termination regions were subjected to the measurement of breakdown voltage, and the cumulative frequency distributions were studied. The devices D1, D2 and D3 are JBS devices which include edge termination regions having the same concentration profiles as the profiles P1, P2 and P3, respectively, illustrated in FIG. 3. The configuration of the devices D1, D2 and D3 is similar to that of the semiconductor device 1000 illustrated in FIG. 1. The results of the measurement of the breakdown voltage are shown in FIG. 4.

The results illustrated in FIG. 4 have shown that the device D3 having no high-concentration regions in the edge termination regions exhibits a lower breakdown voltage than the devices D1 and D2. Further, the device D1 having a higher concentration of the high-concentration regions 121 has been shown to have a higher breakdown voltage than the device D2. From FIG. 4, the median values of breakdown voltage of the devices D1, D2 and D3 are 1510 V, 1410 V and 1280 V, respectively. In the devices, the concentrations and thicknesses of the drift layers 102 are substantially the same, and the device structures are also the same except the concentration profiles. Thus, it is reasonable to ascribe the difference in breakdown voltage among these devices to the difference among the profiles P1, P2 and P3. In this example, it has been shown that the enhancement in breakdown voltage can be obtained when the impurity concentration in the high-concentration regions is, for example, 1×10¹⁹ cm⁻³ or above. Further, it has been shown that the breakdown voltage can be enhanced more effectively when the impurity concentration in the high-concentration regions is 1×10²⁰ cm⁻³ or above.

As mentioned hereinabove, the edge termination regions 151 are provided in order to reduce the field intensity on the surface of the drift layer 102. The reduction in field intensity is associated with the manner in which the depletion layers extend. For example, the field intensity in the edge termination regions 151 is reduced by increasing the number of the FLR regions 154 to easily allow the depletion layers parallel to the surface of the drift layer 102 to extend inside the drift layer 102. A depletion layer formed at a pn junction interface extends both into the p-type region and the n-type region. Increasing the concentration in the p-type region makes it difficult for the depletion layer at the pn junction interface to extend toward the p-type region, thus giving rise to a change in the electric field distribution in the vicinity of the pn junction. This phenomenon causes a change in the manner in which the depletion layers parallel to the surface of the n-type drift layer 102 extend into the drift layer 102, and the field intensity is further reduced as a result.

When the p-type implanted regions are formed by implanting an impurity into silicon carbide, crystal defects may be left in the p-type implanted regions. The presence of such crystal defects in the barrier regions 152 and the guard ring region 153 which are in contact with the first electrode 159 gives rise to a concern that leakage current may occur from the pn junctions formed between the barrier regions 152 and the guard ring region 153, and the n-type drift layer 102. This problem can be avoided by using p-type regions having a lower concentration in the formation of the pn junctions that intersect with the direction perpendicular to the surface of the drift layer 102. Thus, the semiconductor device 1000 that satisfies both high breakdown voltage and low leakage current can be realized by forming the p-type implanted regions that define the edge termination regions and the barrier regions using a combination of the high-concentration regions 121 and the low-concentration regions 122.

As discussed above, the semiconductor devices 1000 having different profiles of the impurity concentration in the edge termination regions exhibit different levels of breakdown voltage even when the concentrations and thicknesses of the drift layers 102 are similar. Thus, controlling the concentration profile makes it possible to realize semiconductor devices 1000 having a high breakdown voltage, and also makes it possible to reduce the forward on-state voltage while ensuring a sufficient level of breakdown voltage. In the manufacturing of, for example, semiconductor devices 1000 that can withstand a reverse voltage of 1000 V, it is often the case that the semiconductor devices 1000 are designed so that the breakdown voltage will be, for example, about 1300 V in consideration of the in-plane distributions of concentration and thickness in the drift layer 102, and the variation in such properties among the drift layers. Assume that, for example, a breakdown voltage of 1300 V is realized by employing the configuration of the device D3 having the concentration profile P3. Here, the concentration and the thickness of the drift layer 102 are written as n3 and d3, respectively. When the device D1 having the concentration profile P1 is fabricated with the same concentration and thickness of the drift layer 102 as in the device D3, the breakdown voltage may be increased to, for example, about 1500 V. In this case, the breakdown voltage is controlled to approximately 1300 V by reselecting the concentration and/or the thickness of the drift layer 102. Because there is a margin of about 200 V by which a decrease in breakdown voltage is acceptable, it is possible to, for example, increase the concentration in the drift layer 102 or to reduce the thickness of the drift layer 102. The increase in concentration and the reduction in thickness of the drift layer 102 both result in a decrease in drift resistance. That is, the device D1, which in this case has the same breakdown voltage as the device D3, exhibits a lower resistance in the forward direction by virtue of the increase in concentration or the reduction in thickness of the drift layer. Thus, the on-state voltage of the semiconductor device 1000 can be reduced.

### (Methods for Manufacturing Semiconductor Devices)

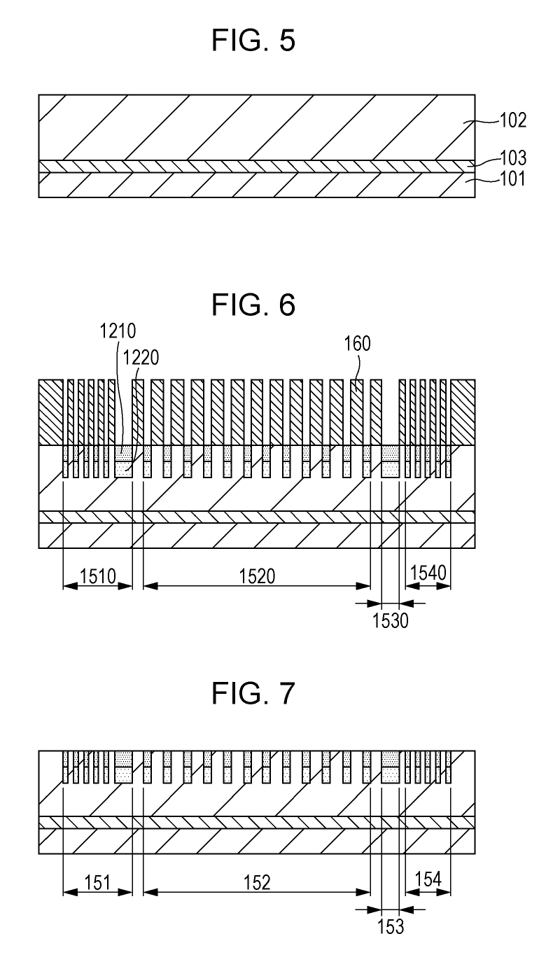

Next, a method for manufacturing the semiconductor device 1000 according to the present embodiment will be described with reference to FIGS. 5 to 13. FIGS. 5 to 13 are sectional views illustrating some of the steps in the method for manufacturing the semiconductor device 1000 according to the present embodiment.

First, a semiconductor substrate 101 is provided. For example, the semiconductor substrate 101 is a low-resistance n-type 4H—SiC offcut substrate having a resistivity of about 0.02 Ωcm.

As illustrated in FIG. 5, a high-resistance n-type drift layer 102 is epitaxially grown on the semiconductor substrate 101. Prior to the formation of the drift layer 102, an n-type SiC buffer layer 103 having a high impurity concentration may be deposited on the semiconductor substrate 101. The impurity concentration in the buffer layer is, for example, 1×10¹⁸ cm⁻³, and the thickness of the buffer layer is, for example, 1 μm. For example, the drift layer 102 is formed of n-type 4H—SiC, and has an impurity concentration of 1×10¹⁶ cm⁻³ and a thickness of 10 μm.

Next, as illustrated in FIG. 6, a mask 160 made of, for example, SiO₂ is formed on the drift layer 102 and thereafter ions, for example, Al ions are implanted into the drift layer 102. Consequently, ion implanted regions 1510, 1520, 1530 and 1540 are formed in the drift layer 102. The ion implanted regions 1510, 1520, 1530 and 1540 will define edge termination regions 151, barrier regions 152, a guard ring region 153 and FLR regions 154, respectively, later in the process.

The ion implanted regions 1510, 1520, 1530 and 1540 include high-concentration implanted regions 1210 under the surface of the drift layer 102, and low-concentration implanted regions 1220 at a greater depth than the high-concentration implanted regions 1210. The magnitudes of ion implantation energy, and the doses may be controlled so that the high-concentration implanted regions 1210 and the low-concentration implanted regions 1220 will have an Al ion concentration profile similar to, for example, the profile P1 or P2 illustrated in FIG. 3. By implanting the ions into the regions at the same time, the profile of the impurity concentration in the direction perpendicular to the principal surface of the semiconductor substrate 101 is rendered identical between the edge termination regions 151 and the barrier regions 152. Further, because the high-concentration implanted regions 1210 and the low-concentration implanted regions 1220 that will later define high-concentration regions 121 and low-concentration regions 122 are formed at the same time using the single mask 160, the outlines of the paired high-concentration regions 121 and low-concentration regions 122 in the edge termination regions 151 and in the barrier regions 152 each become substantially identical as viewed in the direction perpendicular to the principal surface of the semiconductor substrate 101.

Although not illustrated, a first conductivity type impurity may be implanted into the back surface of the semiconductor substrate 101 as required to further increase the first conductivity type concentration on the backside.

Next, as illustrated in FIG. 7, the mask 160 is removed and heat treatment is performed at a temperature of about 1500 to 1900° C. to convert the ion implanted regions 1510, 1520, 1530 and 1540 into edge termination regions 151, barrier regions 152, a guard ring region 153 and FLR regions 154, respectively. In an embodiment, a carbon film may be deposited on the surface of the drift layer 102 before the heat treatment and may be removed after the heat treatment. In this case, a thermal oxide film may be formed on the surface of the drift layer 102 after the removal and the thermal oxide film may be removed by etching to clean the surface of the drift layer 102. The width W of the barrier region 152 in FIG. 1 is, for example, 2 μm, and the spacing S1 between the adjacent barrier regions 152 is, for example, 4 μm. The width of the guard ring region 153 is, for example, about 15 μm. The maximum width S2 of the spacing between the barrier region 152 and the guard ring region 153 in FIG. 1 is set to a distance not more than the spacing S1 and is, for example, 3 μm. The spacing S3 between the guard ring region 153 and the innermost FLR region 154 is, for example, 1 μm.

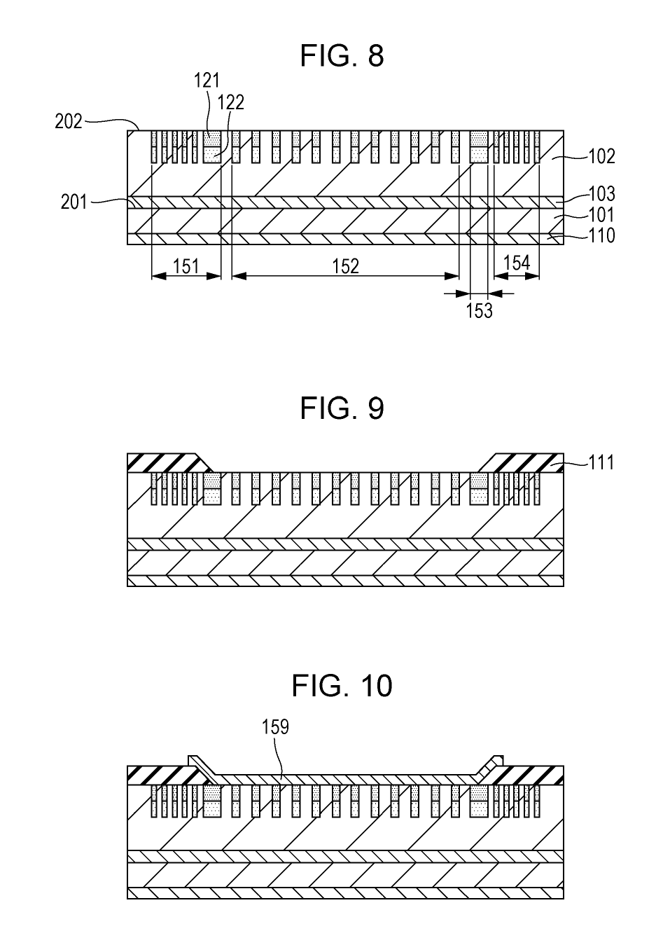

Next, as illustrated in FIG. 8, a second electrode 110 is formed on the backside of the semiconductor substrate 101 by depositing, for example, Ni in a thickness of about 200 nm and heat treating the Ni film at about 1000° C. The second electrode 110 forms an ohmic junction with the back surface of the semiconductor substrate 101.

Next, an insulating film 111 made of, for example, SiO₂ is formed on the surface of the drift layer 102. For example, the thickness of the insulating film 111 is 300 nm. Next, a photoresist mask is formed and the insulating film is treated by, for example, wet etching so as to expose a portion of the guard ring region 153, and the portion of the drift layer 102 enclosed by the guard ring region 153. Thereafter, the mask is removed. In this manner, as illustrated in FIG. 9, an opening is formed in the insulating film 111.

Next, a conductive film for first electrode is deposited so as to cover the entire surface of the perforated insulating film 111 and the drift layer 102 exposed in the opening. The conductive film for first electrode is, for example, a film including a metal such as Ti, Ni or Mo. For example, the thickness of the conductive film for first electrode is 200 nm. After the deposition, a photoresist mask is formed, and the conductive film for first electrode is patterned so that the patterned film covers at least the drift layer 102 exposed from the insulating film 111. A first electrode 159 is thus formed. In the example illustrated in FIG. 10, the periphery of the first electrode 159 is disposed on the insulating film 111. The first electrode 159 is in contact with the portion of the drift layer 102 and the portion of the guard ring region 153 exposed from the insulating film 111. Subsequently, the semiconductor substrate 101 having the first electrode 159 is heat treated at a temperature of 100° C. to 700° C. to form a Schottky junction between the first electrode 159 and the drift layer 102.

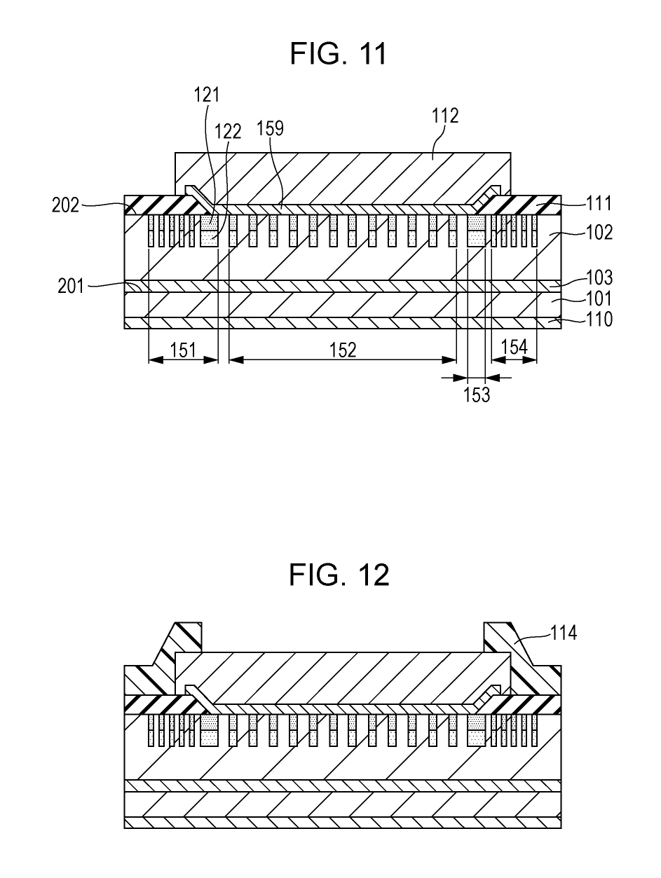

Next, a conductive film for upper electrode is deposited on the first electrode 159 and the insulating film 111. For example, the conductive film for upper electrode is a metal film including Al and having a thickness of about 4 μm. A mask is formed on the conductive film for upper electrode, and a portion of the insulating film 111 is exposed by etching the undesired portion of the conductive film. When the conductive film for upper electrode is treated by wet etching, the conditions of the etching of the conductive film may be controlled so that the first electrode 159 will not be exposed. After the undesired portion of the conductive film for upper electrode is removed by etching, the mask is removed. Consequently, an upper electrode 112 illustrated in FIG. 11 is formed.

Next, a passivation film 114 illustrated in FIG. 12 is formed as required. First, a passivation film 114 made of, for example, SiN is formed on the exposed insulating film 111 and the upper electrode 112. Thereafter, a mask is provided which has an opening that exposes a portion of the passivation film 114 located above the upper electrode 112, and the portion of the passivation film is removed by, for example, dry etching to expose the corresponding portion of the upper electrode 112. Thereafter, the mask is removed. In this manner, as illustrated in FIG. 12, an opening is formed in the passivation film 114 through which the portion of the upper electrode 112 is exposed. The passivation film 114 may be any insulator, and may be, for example, a SiO₂ film or an organic film such as a polyimide film.

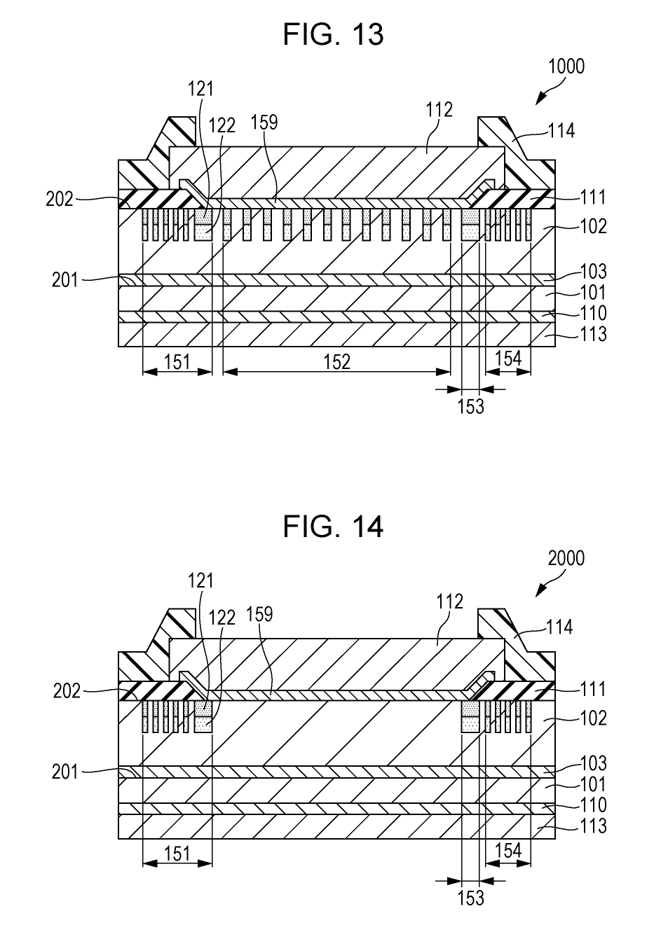

Next, as illustrated in FIG. 13, a backside electrode 113 is formed as required. The backside electrode 113 may be formed before the formation of the passivation film 114, or before the formation of the upper electrode 112. For example, the backside electrode 113 may be formed by depositing Ti, Ni and Ag in this order onto the second electrode 110. The thicknesses of these metal layers are, for example, 0.1 μm, 0.3 μm and 0.7 μm, respectively. A semiconductor device 1000 is manufactured through the steps described above.

### MODIFIED EXAMPLES

Hereinbelow, modified examples of the semiconductor device of the present embodiment will be described.

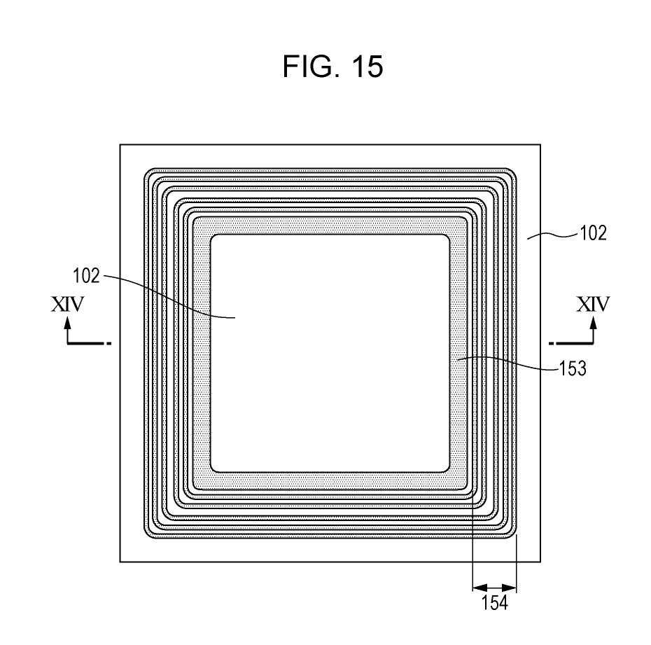

FIG. 14 is a sectional view illustrating a semiconductor device 2000 according to Modified Example 1. FIG. 15 is a plan view illustrating the surface of a silicon carbide semiconductor layer in the semiconductor device 2000. The sectional view in FIG. 14 shows a cross section taken along line XIV-XIV in FIG. 15.

The semiconductor device 2000 in Modified Example 1 has a usual SBD structure without barrier regions. The configuration of the semiconductor device 2000 is the same as that of the semiconductor device 1000 illustrated in FIG. 1 except that the semiconductor device 2000 has no barrier regions. The concentration profile in edge termination regions 151 of the semiconductor device 2000 may be similar to, for example, the profile P1 or P2 illustrated in FIG. 3.

The edge termination regions 151 of the semiconductor device 2000 include high-concentration regions 121 and low-concentration regions 122, and therefore the enhancement in breakdown voltage can be obtained similarly to as described above. The breakdown voltage can be increased over semiconductor devices in which edge termination regions 151 include only one of low-concentration regions and high-concentration regions.

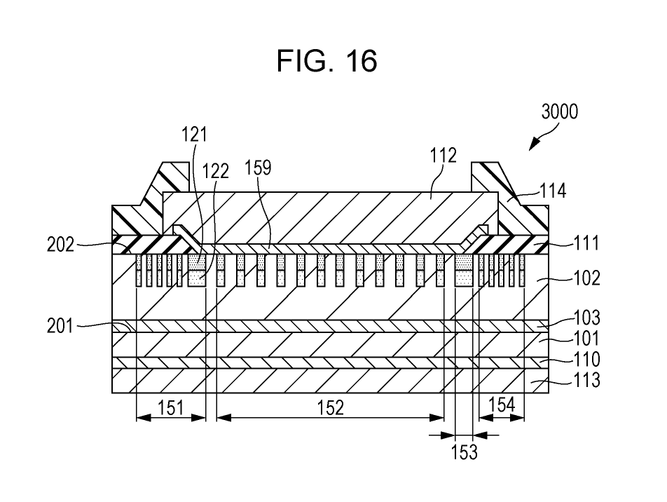

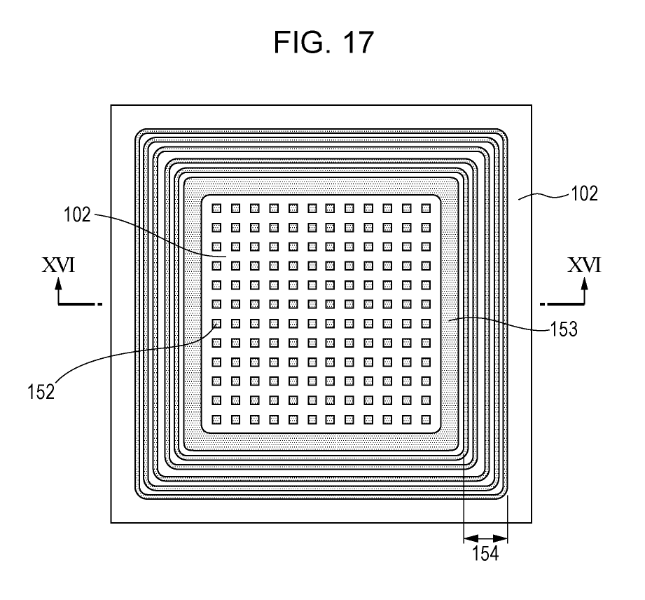

FIG. 16 is a sectional view illustrating a semiconductor device 3000 according to Modified Example 2. FIG. 17 is a plan view illustrating the surface of a silicon carbide semiconductor layer in the semiconductor device 3000. The sectional view in FIG. 16 shows a cross section taken along line XVI-XVI in FIG. 17.

The semiconductor device 3000 in Modified Example 2 is a JBS semiconductor device having a plurality of barrier regions 152. Each of the barrier regions 152 has a flat square shape as viewed from above. The configuration of the semiconductor device 3000 is the same as that of the semiconductor device 1000 illustrated in FIG. 1 except the shape of the barrier regions 152. The concentration profile in edge termination regions 151 of the semiconductor device 3000 may be similar to, for example, the profile P1 or P2 illustrated in FIG. 3.

The edge termination regions 151 of the semiconductor device 3000 include high-concentration regions 121 and low-concentration regions 122, and therefore the enhancement in breakdown voltage can be obtained similarly to as described above. The breakdown voltage can be increased over semiconductor devices in which edge termination regions 151 include only one of low-concentration regions and high-concentration regions. By virtue of having the barrier regions 152, the semiconductor device 3000 achieves a reduction in leakage current as compared to the semiconductor device 2000 having no barrier regions.

The configurations of the semiconductor devices of the present disclosure, and the materials of the components are not limited to those described hereinabove. For example, the materials of the first electrode 159 are not limited to Ti, Ni and Mo described hereinabove. The first electrode 159 may be formed of a material selected from the group consisting of other metals capable of forming a Schottky junction with the drift layer 102, and alloys and compounds of such metals.

In an embodiment, a barrier film including, for example, TiN may be formed between the first electrode 159 and the upper electrode 112. The thickness of the barrier film is, for example, 50 nm.

While the embodiments of the present disclosure have illustrated the silicon carbide as being 4H—SiC, the silicon carbide may be other polytype such as 6H—SiC, 3C—SiC or 15R—SiC. Further, while the embodiments of the present disclosure have illustrated the principal surface of the SiC substrate as being offcut relative to (0001) plane, the principal surface of the SiC substrate may be (11-20) plane, (1-100) plane, (000-1) plane or a plane with an offcut relative to any of these planes. Further, the semiconductor substrate 101 may be a Si substrate. A 3C—SiC drift layer may be formed on the Si substrate. In this case, annealing may be performed at a temperature below the melting point of the Si substrate to activate impurity ions implanted in the 3C—SiC.

What is claimed is:

1. A semiconductor device comprising:
a semiconductor substrate having a first conductivity type and having a principal surface and a back surface;
a silicon carbide semiconductor layer having the first conductivity type and disposed on the principal surface of the semiconductor substrate;
a guard ring region having a second conductivity type and disposed within the silicon carbide semiconductor layer;
a floating region having the second conductivity type and disposed within the silicon carbide semiconductor layer;
a first electrode disposed on the silicon carbide semiconductor layer and forming a Schottky junction with the silicon carbide semiconductor layer; and
a second electrode disposed on the back surface of the semiconductor substrate and forming an ohmic junction with the semiconductor substrate; wherein:
the guard ring region encloses a portion of a surface of the silicon carbide semiconductor layer as viewed in a direction normal to the principal surface;
the first electrode has a surface in contact with the silicon carbide semiconductor layer;
the first electrode is in contact with the guard ring region along an edge portion of the surface of the first electrode in contact with the silicon carbide semiconductor layer;
the floating region is disposed out of contact with the guard ring region, the floating region enclosing the guard ring region as viewed in the direction normal to the principal surface;
the guard ring region and the floating region each include a pair of a high-concentration region having the second conductivity type and a low-concentration region having the second conductivity type;
the high-concentration regions are disposed in contact with the surface of the silicon carbide semiconductor layer;
the low-concentration regions are disposed between the semiconductor substrate and the high-concentration regions; and
the high-concentration regions have an impurity concentration higher than the impurity concentration in the low-concentration regions.

2. The semiconductor device according to claim 1, wherein
each pair of the high-concentration region and the low-concentration region have an identical outline as viewed in the direction normal to the principal surface.

3. The semiconductor device according to claim 1, wherein
the impurity concentration in a direction of depth of the low-concentration regions has a profile including an upward curve.

4. The semiconductor device according to claim 3, wherein
the impurity concentration in the high-concentration regions is not less than 1×10¹⁹ cm⁻³ and the impurity concentration in the low-concentration regions is less than 1×10¹⁹ cm⁻³.

5. The semiconductor device according to claim 3, wherein
the impurity concentration in the high-concentration regions is not less than 1×10²⁰ cm⁻³ and the impurity concentration in the low-concentration regions is less than 1×10²⁰ cm⁻³.

6. The semiconductor device according to claim 1, wherein
the first electrode is an only metal material that is in contact with the guard ring region.

7. The semiconductor device according to claim 1, wherein
the guard ring region does not form an ohmic junction with the first electrode.

8. The semiconductor device according to claim 1, wherein
the first electrode includes a metal selected from the group consisting of Ti, Ni and Mo.

9. The semiconductor device according to claim 1, further comprising:
barrier regions having the second conductivity type and disposed within a portion of the silicon carbide semiconductor layer, the portion enclosed by the guard ring region as viewed in the direction normal to the principal surface, wherein
the impurity concentration in the barrier regions has the same profile in the direction of depth from the surface of the silicon carbide semiconductor layer as the impurity concentration in the guard ring region.

10. The semiconductor device according to claim 9, wherein
each of the barrier regions has a shape extending in a first direction as viewed in the direction normal to the principal surface;
the barrier regions are arranged with a first spacing in a second direction perpendicular to the first direction; and
both ends in the first direction of each of the barrier regions are connected to the guard ring region.

11. The semiconductor device according to claim 10, wherein
of the barrier regions, the barrier region nearest to the guard ring region as viewed in the direction normal to the principal surface is adjacent to the guard ring region with a second spacing, and the second spacing has a maximum width in the second direction that is equal to or less than the first spacing.

12. The semiconductor device according to claim 11, wherein
the guard ring region as viewed in the direction normal to the principal surface is adjacent to the floating region with a third spacing in the second direction, the third spacing being equal to or less than the maximum width.

13. The semiconductor device according to claim 1, further comprising:
an insulating film covering at least a portion of the guard ring region; and
an upper electrode disposed on an upper surface of the first electrode;
the upper electrode covering the upper surface and a side surface of the first electrode; wherein
a side surface of the upper electrode is disposed on the insulating film.
